(19) United States
(12) Patent Application Publication
(10) Pub. No.: US 2025/0157880 A1
(43) Pub. Date: May 15, 2025

(54) POWER CONVERSION DEVICE

(71) Applicant: HITACHI ASTEMO, LTD., Hitachinaka-shi, Ibaraki (JP)

(72) Inventor: Fusanori NISHIKIMI, Hitachinaka-shi, Ibaraki (JP)

(73) Assignee: HITACHI ASTEMO, LTD., Hitachinaka-shi, Ibaraki (JP)

(21) Appl. No.: 18/835,101

(22) PCT Filed: Mar. 25, 2022
(86) PCT No.: PCT/JP2022/014685

§ 371 Date: Aug. 1, 2024

(51) Int. Cl. H01L 23/427; H01L 23/373; H01L 25/07

(52) U.S. Cl. CPC H01L 23/427; H01L 23/373; H01L 25/072

(57) ABSTRACT

A power conversion device includes: a power module including a conductor portion extending laterally; and a cooler that cools the power module. The cooler includes a first member not in contact with the power module, and a second member having one surface, a part of which is attached to the first member, and another surface in contact with the power module. The second member is provided with a thin portion in which a thickness between the one surface and the other surface decreases to increase an insulation distance from the conductor portion to the cooler in an extending direction of the conductor portion.

### TECHNICAL FIELD

The present invention relates to a power conversion device.

### BACKGROUND ART

Power modules incorporated in a power conversion device often require a cooling mechanism because of a large amount of heat generation. Meanwhile, power conversion devices have various needs such as downsizing and securing an insulation distance. PTL 1 discloses a power conversion device including: a semiconductor module which includes a module body incorporating a semiconductor element, and a plurality of power terminals and a plurality of control terminals protruding from the module body; and a plurality of cooling pipes which are arranged in a stacked manner to hold the semiconductor module from both major surfaces of the semiconductor module, wherein the plurality of power terminals protrude from the module body in a same direction in a height direction that is perpendicular to a stacking direction in which the cooling pipes and the semiconductor module are stacked, the plurality of control terminals protrude from the module body in a same direction in the height direction, each of the cooling pipes includes a pair of outer shell plates which are electrically conductive and face each other in the stacking direction, and a refrigerant flow path formed between the pair of outer shell plates, each of the pair of outer shell plates includes a flow-path forming portion that forms the refrigerant flow path between the outer shell plates, and a flow-path outer periphery formed around the flow-path forming portion as viewed in the stacking direction, the flow-path outer periphery of at least one of the pair of outer shell plates includes an outer shell protrusion on at least one side in the height direction with respect to the flow-path forming portion, the outer shell protrusion has a protruding length from the flow-path forming portion, the protruding length being greater than a protruding length of a side outer periphery of the flow-path outer periphery, the side outer periphery protruding outward from the flow-path forming portion in a lateral direction that is perpendicular to the height direction and the stacking direction, and the outer shell protrusion overlaps at least one of the plurality of power terminals and the plurality of control terminals in the stacking direction.

### CITATION LIST

### Patent Literature

PTL 1: JP 2018-148176 A

### SUMMARY OF INVENTION

### Technical Problem

In the invention described in PTL 1, there is room for improvement in securing an insulation distance.

### Solution to Problem

A power conversion device according to a first aspect of the present invention includes: a power module including a conductor portion extending laterally; and a cooler that cools the power module. In the power conversion device, the cooler includes a first member not in contact with the power module, and a second member having one surface, a part of which is attached to the first member, and another surface in contact with the power module, and the second member is provided with a thin portion in which a thickness between the one surface and the other surface decreases to increase an insulation distance from the conductor portion to the cooler in an extending direction of the conductor portion.

### Advantageous Effects of Invention

According to the present invention, an insulation distance can be secured.

### BRIEF DESCRIPTION OF DRAWINGS

FIG. 1 is an exploded perspective view of a power conversion device.

FIG. 2 is an external view of the power conversion device.

FIG. 3 is a cross-sectional view taken along line III-III in FIG. 2.

FIG. 4 is a diagram illustrating a comparison between the power conversion device according to the present embodiment and a comparative device as a comparative example.

FIG. 5 is a schematic diagram illustrating a transfer molding process of a power module.

FIG. 6 is a diagram illustrating shapes of an upper cooler according to a second modification.

FIG. 7 is a diagram illustrating a shape of the thin portion according to a fifth modification.

FIG. 8 is a diagram illustrating a shape of the upper cooler according to a seventh modification.

FIG. 9 is a diagram illustrating heat dissipation materials according to an eighth modification.

FIG. 10 is a diagram illustrating a spatial distance according to a ninth modification.

### DESCRIPTION OF EMBODIMENTS

### Embodiment

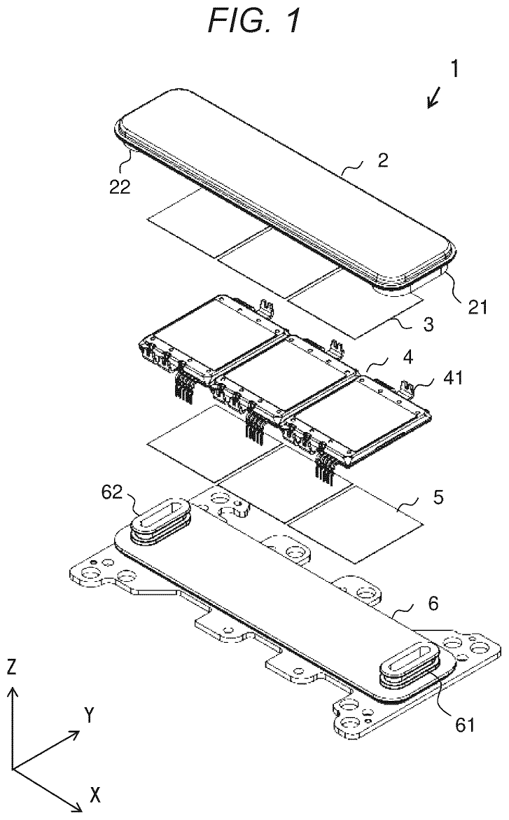

Hereinafter, an embodiment of a power conversion device will be described with reference to FIGS. 1 to 5.

FIG. 1 is an exploded perspective view of a power conversion device 1. In the present embodiment, XYZ-axes, which are three common orthogonal axes, are defined in order to clearly show a mutual relationship in the drawings. The power conversion device 1 includes an upper cooler 2, an upper heat dissipation material 3, three power modules 4, a lower heat dissipation material 5, and a lower cooler 6. In FIG. 1, the upper cooler 2, the upper heat dissipation material 3, the power modules 4, the lower heat dissipation material 5, and the lower cooler 6 are arranged in the Z-axis direction. In each power module 4, a power semiconductor element is sealed with resin. Details will be described later.

The upper heat dissipation material 3 and the lower heat dissipation material 5 are very thin, exhibit high heat conductivity, and have insulating properties. The upper heat dissipation material 3 improves the contact between the upper cooler 2 and the power modules 4. The lower heat dissipation material 5 improves the contact between the lower cooler 6 and the power modules 4. The power module 4 converts between AC power and DC power. The power module 4 includes a plurality of conductor portions 41. A positive DC terminal, a negative DC terminal, an AC terminal, and a signal terminal are collectively referred to as the conductor portions 41. The power modules 4 generate a large amount of heat, and thus are cooled using the upper cooler 2 and the lower cooler 6.

The upper cooler 2 includes an upper first opening 21 at an end portion on the X-axis positive side and an upper second opening 22 at an end portion on the X-axis negative side. The upper first opening 21 and the upper second opening 22 are open to the Z-axis negative side, and have shaft seals around the openings. The lower cooler 6 includes a lower first opening 61 at an end portion on the X-axis positive side and a lower second opening 62 at an end portion on the X-axis negative side. The lower first opening 61 and the lower second opening 62 are open to the Z-axis negative side, and have shaft seals around the openings. In the assembled power conversion device 1, the upper first opening 21 and the lower first opening 61 are connected to each other, and the upper second opening 22 and the lower second opening 62 are connected to each other.

The lower cooler 6 further has a refrigerant inlet and a refrigerant outlet (not illustrated). A refrigerant is introduced into the lower cooler 6 through the refrigerant inlet, and flows into the upper cooler 2 from the lower first opening 61 via the upper first opening 21. The refrigerant that has cooled the upper cooler 2 returns to the lower cooler 6 from the upper second opening 22 via the lower second opening 62, and discharged from the refrigerant outlet (not illustrated).

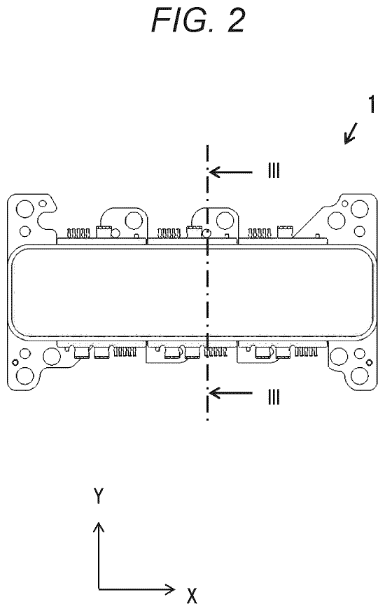

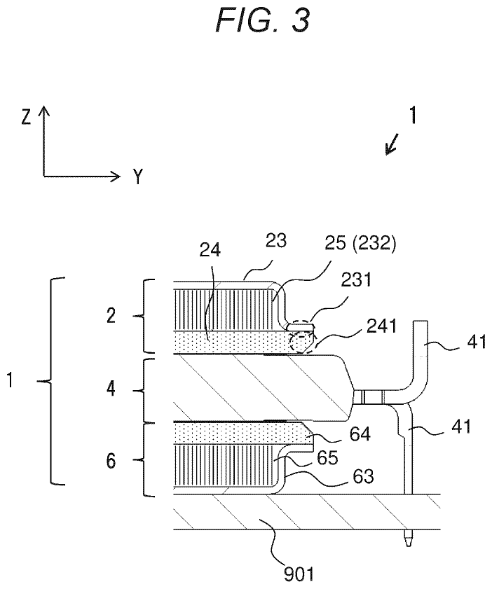

FIG. 2 is an external view of the power conversion device 1. The power conversion device 1, which is disassembled in the Z-direction in FIG. 1, is assembled in FIG. 2. A one-dot chain line in FIG. 2 indicates a positional relationship with FIG. 3.

FIG. 3 is a cross-sectional view taken along line III-III in FIG. 2. However, for convenience of drawing, only the Y-axis positive side of the power conversion device 1 is illustrated, and the Y-axis negative side half of the power conversion device 1 is not illustrated. FIG. 3 illustrates a state in which the power conversion device 1 is fixed to a substrate 901. In addition, since the upper heat dissipation material 3 and the lower heat dissipation material 5 are thin, they are not illustrated in FIG. 3. The power module 4 includes conductor portions 41 extending in the Y-axis direction from a side surface. To be precise, the conductor portions 41 extend in the Y-axis direction and then bends in the Z-axis positive direction or the Z-axis negative direction.

The position from which the conductor portions 41 extend in the Y-axis direction is not at the center of the power module 4 in the thickness direction but is offset in the Z-axis direction. Specifically, it is offset to the Z-axis negative side. As will be described later, although there is a manufacturing advantage due to the offset of the position from which the conductor portions 41 extend, there is an issue that an insulation distance is shortened on the offset side. However, in the present embodiment, this issue is solved by providing a thin portion 241 to be described later.

The upper cooler 2 includes a first member 23 and a second member 24. The first member 23 has a recessed central portion and a flange portion 231 around the entire circumference. The second member 24 has a substantially flat plate shape, and is attached to the flange portion 231 of the first member 23 by a brazing method. A region that is formed by the recess of the first member 23 and is closed by the second member 24 is a flow path space 25.

The flow path space 25, which is a region indicated by vertical hatching, is surrounded by the first member 23 and the second member 24. The flow path space 25 has a built-in fin to improve cooling efficiency. A surface of the second member 24 on the Z-axis negative side is in contact with the power module 4 via the upper heat dissipation material 3, and a surface thereof on the Z-axis positive side is attached to the first member 23 by a brazing method at a position P1. The second member 24 has a thin portion 241 at an end portion in the Y-axis positive direction. The thin portion 241 has a tapered shape in a cross-sectional view. The first member 23 side of the thin portion 241 is flat and smooth to be in contact with the flange portion 231, and is not in contact with the power module 4.

It is desirable that the first member 23 and the second member 24 are made of a material having high heat conductivity. The first member 23 and the second member 24 may be made of the same material or different materials. The thickness of the first member 23 and the thickness of the second member 24 may not be the same. It is desirable that the first member 23 is relatively thin so as to facilitate processing, and the second member 24 is thick enough to secure rigidity. The lower cooler 6 includes a lower first member 63, a lower second member 64, and a lower flow path space 65. In the range illustrated in FIG. 3, the lower cooler 6 has a shape vertically symmetrical to that of the upper cooler 2. Thus, the configuration of the upper cooler 2 will be described in detail below, and the lower cooler 6 will not be described.

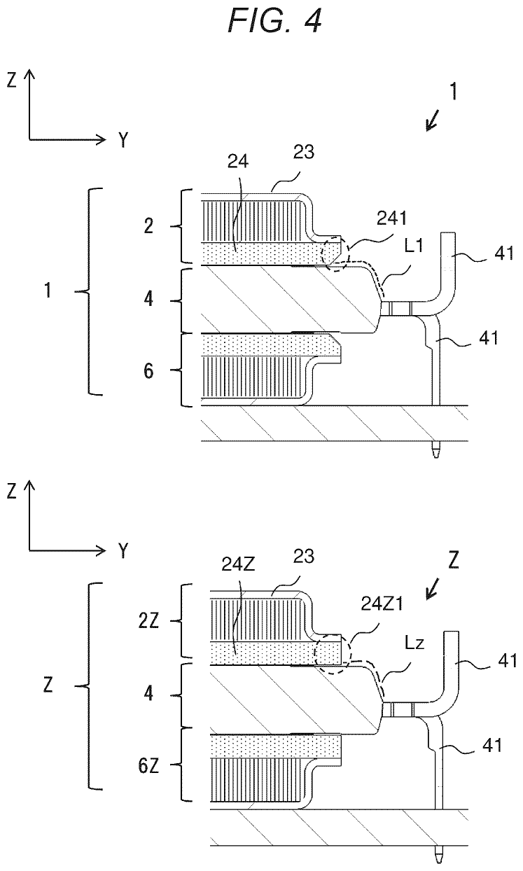

FIG. 4 is a diagram illustrating a comparison between the power conversion device 1 according to the present embodiment and a comparative device Z as a comparative example. The comparative device Z has the same configuration as the power conversion device 1 except for the upper cooler 2 and the lower cooler 6. The comparative device Z includes a comparative upper cooler 2Z instead of the upper cooler 2 and a comparative lower cooler 6Z instead of the lower cooler 6. At least in the range illustrated in FIG. 4, the shapes of the comparative upper cooler 2Z and the comparative lower cooler 6Z are symmetrical to each other, and thus the comparative upper cooler 2Z will be described below.

The comparative upper cooler 2Z includes a first member 23 and a comparative second member 24Z. That is, the first member 23 of the comparative upper cooler 2Z is the same as the first member 23 of the upper cooler 2. The comparative second member 24Z is different from the second member 24 in that the comparative second member 24Z has no thin portion 241 and has a constant thickness in the Y-axis direction. Specifically, the entire Z-axis negative side of a comparative end portion 24Z1, which is an end portion of the comparative upper cooler 2Z, is in contact with the power module 4.

In the power conversion device 1 illustrated in the upper part of FIG. 4, an implemented creepage distance L1, which is an insulation distance, more precisely, a creepage distance between the conductor portion 41 and the upper cooler 2, is as indicated by a dotted line. In the comparative device Z illustrated in the lower part of FIG. 4, a comparative creepage distance Lz, which is a creepage distance between the conductor portion 41 and the comparative upper cooler 2Z, is as indicated by a long broken line.

In the power conversion device 1, the thin portion 241 exists to keep the end portion on the Y-axis positive side from contacting the power module 4, so that the implemented creepage distance L1 is longer than the comparative creepage distance Lz. That is, in the present embodiment, it is possible to increase the insulation distance between the conductor portion 41 and the upper cooler 2 while keeping the shape and size of the first member 23 the same and the volume of the flow path space 25 constant. In the present embodiment, since the position from which the conductor portions 41 extend is offset to the Z-axis negative side, the insulation distance is shorter on the Z-axis negative side than on the Z-axis positive side. Therefore, the effect of increasing the insulation distance by providing the thin portion 241 is greater on the side to which the position from which the conductor portions 41 extend is offset, or the Z-axis negative side.

### (Resin Sealing)

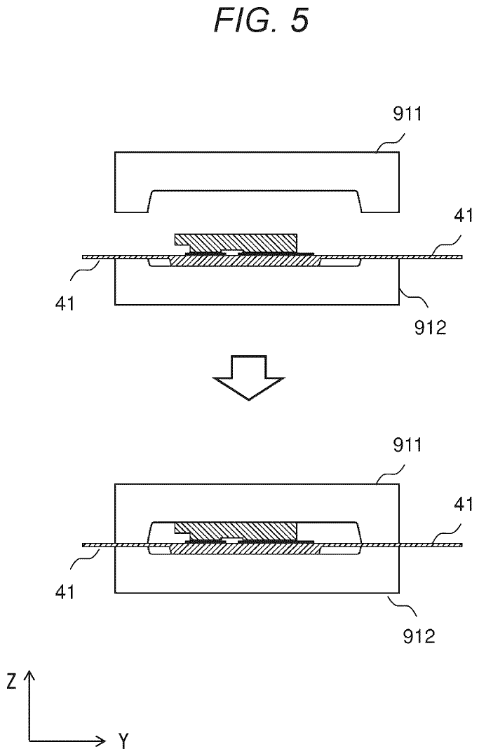

FIG. 5 is a schematic diagram illustrating a transfer molding process of a sealing resin in the power module 4. That is, the power modules 4 illustrated in FIG. 1 etc. have been subjected to the process illustrated in FIG. 5. Here, the power module 4 before being sealed with resin is referred to as a “primary assembly” 4B. The upper part of FIG. 5 illustrates a longitudinal cross-sectional view before mold clamping, and the lower part of FIG. 5 illustrates a longitudinal cross-sectional view after mold clamping.

As illustrated in the upper part of FIG. 5, the primary assembly 4B is set between an upper mold 911 and a lower mold 912 created in advance. The upper mold 911 and the lower mold 912 sandwich the primary assembly 4B on mold pressing surfaces from above and below and are clamped, so that a mold space is formed within the mold as illustrated in the lower part of FIG. 5. By filling the mold space with a sealing resin to perform the molding, the primary assembly 4B is sealed with the sealing resin to become the power module 4.

On the mold pressing surfaces, the positive DC terminal, the negative DC terminal, the AC terminal, and the signal terminal, which are the conductor portions 41, are arranged in substantially the same plane. With such arrangement of the terminals, mold clamping using the upper mold 911 and the lower mold 912 can be performed without generating an extra stress at a connection portion between each terminal and the power semiconductor element as well as without any gaps. Therefore, the power semiconductor element can be sealed without damage to the power semiconductor element or leakage of the sealing resin from a gap.

According to the above-described embodiment, the following operational effects can be obtained.
(1) A power conversion device 1 includes a power module 4 including a conductor portion 41 extending laterally, and an upper cooler 2 that cools the power module 4. The upper cooler 2 includes a first member 23 not in contact with the power module 4, and a second member 24 having a surface on the Z-axis positive side, a part of which is attached to the first member 23, and a surface on the Z-axis negative side in contact with the power module 4. The second member 24 is provided with a thin portion 241 in which a thickness in the Z-axis direction decreases to increase an insulation distance from the conductor portion 41 in an extending direction of the conductor portion 41, or the Y-axis direction. Therefore, the insulation distance of the conductor portion 41 in the power conversion device 1 can be secured. This makes it easy to secure a specified insulation distance of the conductor portion 41 even if the power conversion device 1 is downsized.
(2) The thickness of the second member 24 is larger than the thickness of the first member 23. Therefore, molding is easy at the time of brazing between the first member 23 and the second member 24. In addition, the flexural strength of the second member 24 is improved and thus deformation such as warpage can be suppressed, which makes it easy to bring the second member 24 into close contact with the power module 4. Furthermore, press molding is easier when the first member 23 is thinner.
(3) The first member 23 includes a recessed portion 232 that forms a space through which a refrigerant flows, and a flange portion 231 that surrounds the recessed portion 232 and is connected to the second member 24. The second member 24 has a flat plate shape with the surface on the Z-axis negative side shorter than the surface on the Z-axis positive side in the extending direction of the conductor portion 41. Therefore, an arbitrary insulation distance can be set by changing the thickness of the second member 24.
(4) The power conversion device 1 includes two sets of coolers, namely, the upper cooler 2 and a lower cooler 6. The upper cooler 2 and the lower cooler 6 sandwich the power module 4 from both sides in the Z-axis direction. Therefore, the cooling efficiency of the power module 4 can be improved. In addition, even with the double-sided cooling structure, the insulation distance of the conductor portion 41 in the power conversion device 1 can be secured.
(5) The conductor portion 41 is offset in either sandwiching direction of the upper cooler 2 and the lower cooler 6, or the Z-axis direction, for extension. Therefore, molding of the power module 4 is easy. In addition, the insulation distance can be arbitrarily set by adjusting the thin portion 241. Furthermore, a plurality of power modules 4 can be easily cooled by one cooler. Specifically, when a plurality of power modules 4 are cooled by one cooler, respective conductor portions 41 do not interfere with each other due to the offset of the conductor portions 41 in the Z-axis direction.
(6) The thin portion 241 has a tapered shape in a cross-sectional view. Therefore, the thin portion 241 can be easily molded, which is expected to improve productivity. The tapered shape can be molded also by pressing. Alternatively, even in a case where cutting is performed to create the shape, the tapered shape can be easily formed because the cutting is chamfering, which is a general-purpose process and thus does not require a special blade.
(7) The first member 23 and the thin portion 241 of the second member 24 are connected to each other by brazing.

### First Modification

In the above-described embodiment, the second member 24 is thicker than the first member 23. However, the first member 23 and the second member 24 may have the same thickness, or the second member 24 may be thinner than the first member 23.

### Second Modification

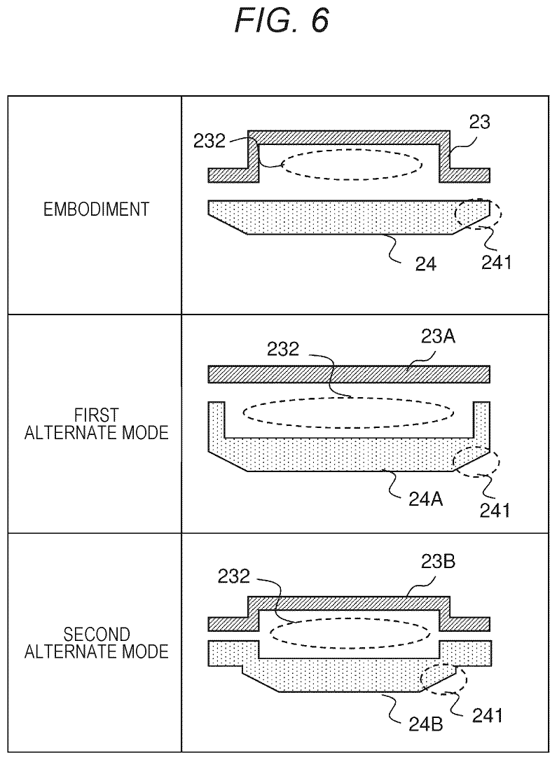

FIG. 6 is a diagram illustrating shapes of the upper cooler 2 according to a second modification. FIG. 6 illustrates the upper cooler 2 according to the above-described embodiment, a first alternate mode, and a second alternate mode. In the upper cooler 2 according to the embodiment illustrated in the upper row, the first member 23 has the recessed portion 232. However, the second member 24 may have a recessed portion 232 as in the first alternate mode, or the first member 23 and the second member 24 may have recessed portions 232 as in the second alternate mode. Further, the first member 23 and the second member 24 may have no flange portion as in the first alternate mode, or may have respective flange portions.

### Third Modification

In the above-described embodiment, the power conversion device 1 includes the upper cooler 2 and the lower cooler 6. However, the power conversion device 1 may include at least one of the upper cooler 2 and the lower cooler 6. In a case where one of the upper cooler 2 and the lower cooler 6 is not provided, the corresponding heat dissipation material is not required. For example, in a case where the upper cooler 2 is not provided, the power conversion device 1 may not include the upper heat dissipation material 3 either.

### Fourth Modification

In the above-described embodiment, the conductor portion 41 extends in the Y-axis direction from the position offset in the Z-axis direction instead of the center of the power module 4 in the width direction. However, the conductor portion 41 may extend in the Y-axis direction from the center of the power module 4 in the width direction.

### Fifth Modification

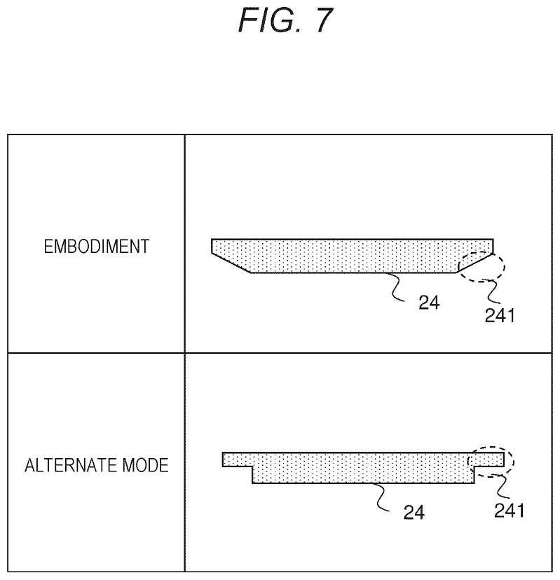

FIG. 7 is a diagram illustrating a shape of the thin portion 241 according to a fifth modification. In the above-described embodiment, the thin portion 241 has a tapered shape in a cross-sectional view. However, the shape of the thin portion 241 is not limited to a tapered shape. For example, a step may be provided as illustrated in FIG. 7.

### Sixth Modification

In the above-described embodiment, the flange portion 231 of the first member 23 and the thin portion 241 of the second member 24 are connected to each other by brazing. However, the connection method between the flange portion 231 and the thin portion 241 is not limited to brazing. For example, they may be connected with an adhesive or may be fixed with a screw.

### Seventh Modification

In the above-described embodiment, the place where the thin portion 241 is formed is not particularly limited. The thin portion 241 may be formed around the entire circumference, or may be separately formed at positions corresponding to the positions from which the conductor portions 41 extend.

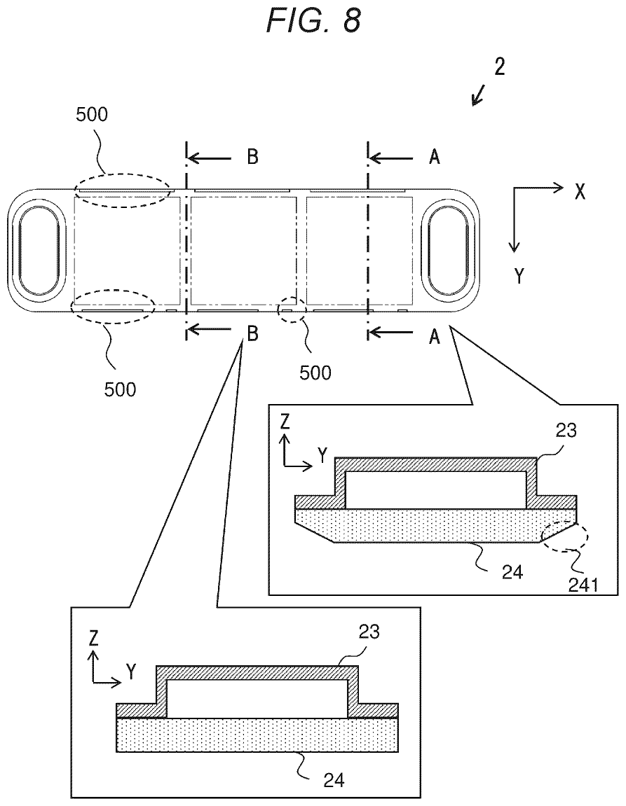

FIG. 8 is a diagram illustrating a shape of the upper cooler 2 according to a seventh modification. Reference sign 500 in FIG. 8 denotes a position from which a conductor portion 41 extends. An A-A cross section in FIG. 8 corresponds to a position from which a conductor portion 41 extends, and a B-B cross section corresponds to a position from which no conductor portion 41 extends. In the cross-sectional view taken along line A-A, the upper cooler 2 has the same shape as the upper cooler 2 illustrated in FIG. 3 in the embodiment, and includes the thin portion 241. In the cross-sectional view taken along line B-B, the upper cooler 2 does not include the thin portion 241.

According to the present modification, the following operational effects can be obtained.
(8) The thin portion 241 is separately formed at a position corresponding to a position from which the conductor portion 41 extends. Therefore, the balance between the strength of the upper cooler 2 and the lower cooler 6 and the insulation distance can be secured.

### Eighth Modification

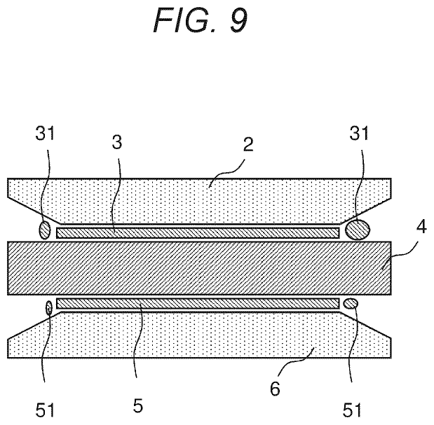

FIG. 9 is a diagram illustrating presence of heat dissipation materials, namely, the upper heat dissipation material 3 and the lower heat dissipation material 5 according to an eighth modification. However, in FIG. 9, in order to emphasize the presence of heat dissipation materials, the scale thereof is inaccurate and a space is provided between the heat dissipation material and another component. Since the upper heat dissipation material 3 and the lower heat dissipation material 5 are very thin, the thickness of the upper heat dissipation material 3 and the lower heat dissipation material 5 would actually be equal to or less than the thickness of the lines in the scale of FIG. 9.

In the present modification, a part of the upper heat dissipation material 3 that is not sandwiched between the upper cooler 2 and the power module 4 is retained between the thin portion 241 of the upper cooler 2 and the power module 4 as a retained upper heat dissipation material 31. Similarly, a part of the lower heat dissipation material 5 that is not sandwiched between the lower cooler 6 and the power module 4 is also retained as a retained lower heat dissipation material 51.

According to the present modification, the following operational effects can be obtained.
(9) An upper heat dissipation material 3 is provided between the surface of the upper cooler 2 on the Z-axis negative side and the power module 4. A part of the upper heat dissipation material 3 is retained under the thin portion 241. Therefore, protrusion of the upper heat dissipation material 3 toward the conductor portion 41 is reduced, and productivity is improved. This is specifically as follows. The thin portion 241 serves as a heat dissipation material reservoir, so that an application amount of the heat dissipation material can be roughly controlled as compared with the case without the thin portion 241. If the heat dissipation material protrudes, adhesion to the equipment or other parts would affect insulation design of a component other than the present component. In addition, there is also a risk that the protruded heat dissipation material is separated to cause internal contamination. However, retaining the heat dissipation material under the thin portion 241 prevents these issues.

### Ninth Modification

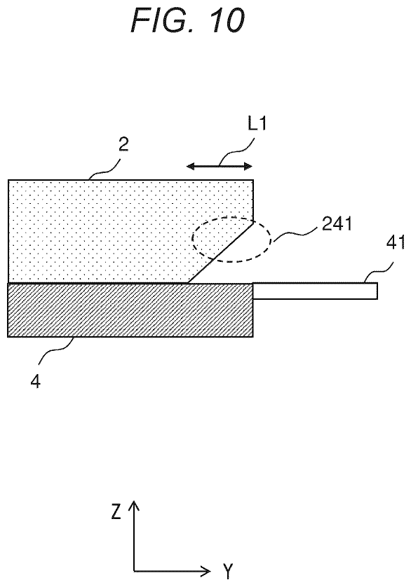

FIG. 10 is a diagram illustrating a spatial distance according to a ninth modification. As illustrated in FIG. 10, the conductor portion 41 may be formed at an end portion of the power module 4 in the Z-axis positive direction or negative direction. In this case, the creepage distance and the spatial distance are the same as a distance L1, and thus it can be said that the thin portion 241 contributes to securing not only the creepage distance but also the spatial distance.

The above-described modifications may be combined. Although various embodiments and modifications have been described above, the present invention is not limited to these contents. Other aspects conceivable within the scope of the technical idea of the present invention are also included within the scope of the present invention.

### REFERENCE SIGNS LIST

1 power conversion device
2 upper cooler
3 upper heat dissipation material
4 power module
5 lower heat dissipation material
6 lower cooler
11 control device
23 first member
24 second member
41 conductor portion
63 lower first member
64 lower second member
231 flange portion
241 thin portion

1. A power conversion device comprising:
a power module including a conductor portion extending laterally; and
a cooler that cools the power module,
wherein the cooler includes a first member not in contact with the power module, and a second member having one surface, a part of which is attached to the first member, and another surface in contact with the power module, and
the second member is provided with a thin portion in which a thickness between the one surface and the other surface decreases to increase an insulation distance from the conductor portion to the cooler in an extending direction of the conductor portion.

2. The power conversion device according to claim 1, wherein a thickness of the second member is larger than a thickness of the first member.

3. The power conversion device according to claim 1, wherein
the first member includes a recessed portion that forms a space through which a refrigerant flows, and a flange portion that surrounds the recessed portion and is connected to the second member, and
the second member has a flat plate shape with the other surface shorter than the one surface in the extending direction of the conductor portion.

4. The power conversion device according to claim 1, wherein
the power conversion device includes two sets of the coolers, and
the two sets of the coolers sandwich the power module from both sides.

5. The power conversion device according to claim 4, wherein the conductor portion is offset in either sandwiching direction of the coolers for extension.

6. The power conversion device according to claim 1, wherein the thin portion has a tapered shape in a cross-sectional view.

7. The power conversion device according to claim 1, wherein the first member and the thin portion of the second member are connected to each other by brazing.

8. The power conversion device according to claim 1, wherein the thin portion is separately formed at a position corresponding to a position from which the conductor portion extends.

9. The power conversion device according to claim 1, wherein
a heat dissipation material is provided between the other surface of the cooler and the power module, and
a part of the heat dissipation material is retained between the thin portion and the power module.
